(19) United States
(12) Patent Application Publication
(10) Pub. No.: US 2025/0280583 A1
(43) Pub. Date: Sep. 4, 2025

(54) METHOD FOR PRODUCING A POWER FINFET

(71) Applicant: Robert Bosch GmbH, Stuttgart (DE)

(72) Inventor: Daniel Krebs, Aufhausen (DE)

(21) Appl. No.: 19/065,749

(22) Filed: Feb. 27, 2025

(30) Foreign Application Priority Data
Mar. 1, 2024 (DE) 10 2024 201 962.3

(51) Int. Cl. H10D 64/01; H10D 30/01; H10D 30/62; H10D 62/60; H10D 62/832; H10D 62/85; H10D 64/27

(52) U.S. Cl. CPC H10D 64/027; H10D 30/024; H10D 30/62; H10D 62/60; H10D 62/8325; H10D 62/8503; H10D 64/513

(57) ABSTRACT

A method for producing a power FinFET with control electrodes. The power FinFET includes a semiconductor body which includes a second connection region and a drift layer. The second connection region forms a front side of the semiconductor body. The method includes: creating a first structured mask on the front side of the semiconductor body using a first lithography step, wherein the first structured mask includes oxide regions, first open regions and second open regions, wherein the first open regions and the second open regions expose the front side of the semiconductor body; creating first trenches below the first open regions of the mask and second trenches below the second open regions of the mask using a first etching process starting from the front side of the semiconductor body into the drift layer, wherein the first and second trenches trenches are arranged substantially parallel to one another and alternate.

### FIELD

The present invention relates to a method for producing a power FinFET by means of lithography masks and to a corresponding power FinFET.

### BACKGROUND INFORMATION

In power electronics, semiconductors with a wide band gap such as SiC or GaN are used. Typically, power MOSFETs with a vertical channel region (so-called TMOSFETs) are used.

In the TMOSFET design, the n+ source situated in a semiconductor material and the p channel region are interrupted by trenches that can extend up to an n− drift region. Inside the trench, there is a gate electrode, which is separated from the semiconductor material by a gate oxide and is used for controlling the channel region. By suitable selection of the geometry, epitaxial doping, channel doping and screening doping, the on-resistance, threshold value voltage, short-circuit resistance, oxide load and breakdown voltage of the TMOSFET can be optimized.

To increase the breakdown voltage of such power MOSFETs, shielding regions are arranged below the trenches.

Since these shielding regions are connected to the source regions, it may be necessary to arrange two-part control electrodes within the trenches, as described in DE 10224201 B4.

A disadvantage here is that the trenches have to be relatively wide, so the pitch dimension and the on-resistance of the power MOSFET are large.

Between the shielding regions, which are usually p-doped, a so-called JFET is formed between two adjacent trenches, which serves to limit the current through the channel region in the event of a short circuit. For this purpose, p-doped shielding regions are implanted using a lithographically structured mask.

A disadvantage here is that due to process fluctuations, the distances between two p-doped shielding regions vary and consequently the limiting of a short-circuit current is unintentionally influenced.

### SUMMARY

The present invention provides, among other things, a production method for producing a power FinFET, and a power FinFET.

Preferred example embodiments of the present invention are disclosed herein.

According to a first aspect, the present invention provides a method for producing a power FinFET having control electrodes. According to an example embodiment of the present invention, the power FinFET comprises a semiconductor body which comprises a second connection region and a drift layer, wherein the second connection region forms a front side of the semiconductor body, the method comprising the steps of:
Creating a first structured mask on the front side of the semiconductor body with the aid of a first lithography step, wherein the first structured mask comprises oxide regions, first open regions and second open regions, wherein the first open regions and the second open regions expose the front side of the semiconductor body,
Creating first trenches below the first open regions of the mask and second trenches below the second open regions of the mask with the aid of a first etching process starting from the front side of the semiconductor body into the drift layer, wherein the first trenches and the second trenches are arranged substantially parallel to one another and alternate, wherein the second trenches comprise substantially the same width as the first trenches, applying a polysilicon layer to the front side of the semiconductor body so that the first trenches and the second trenches are filled, applying an isotropic oxide layer to the front side of the semiconductor body,
Creating a second structured mask on the isotropic oxide layer using a second lithography step, wherein the second structured mask is open above the first trenches, removing the isotropic oxide layer above the first trenches with the aid of a second etching process, removing the polysilicon layer within the first trenches with the aid of a third etching process, creating shielding regions below the first trenches with the aid of a first implantation process, removing the isotropic oxide layer above the second trenches and the polysilicon layer within the second trenches with the aid of a fourth etching process, oxidizing the front side so that a further oxide layer is arranged on the front side, widening the first trenches and the second trenches with the aid of a fifth etching process so that fins are formed between the first trenches and the second trenches, wherein the fins preferably comprise a width of less than 500 nm, activating the shielding regions by means of annealing, and creating control electrodes within the first trenches and within the second trenches.

In one possible embodiment of the production method of the present invention, in order to create the control electrodes an electrode material for the control electrodes, in particular polysilicon, is deposited in a layer thickness in such a way that the trenches are completely filled, wherein after a subsequent etching process the trenches remain completely filled with the electrode material for the control electrodes.

The contact to the p-shielding regions below every second trench is therefore not made by a contact in the trench, but by a contact at the end of the cell field, or by a deep p-terminal region implanted at periodic intervals along the fin.

An advantage of the production method of the present invention is that a short-circuit current-limiting effect occurs between the shielding region and the side walls of the second trenches. As a result, process fluctuations can be tolerated. Although a second lithography mask is used to open the first trenches, the position of the shielding implantation is not subject to any adjustment tolerance since the position of the shielding region is defined by the trenches themselves.

In a development of the present invention, the first structured mask has nitride regions, wherein the oxide regions are arranged on the nitride regions.

The advantage here is that oxidation of the fin top is prevented.

In a further embodiment of the present invention, spreading regions below the second trenches are created with the aid of a second implantation process, wherein the second implantation energy comprises a value between 60 keV and 2500 keV.

The advantage here is that the on-resistance of the power FinFET is reduced.

In a development of the present invention, the first etching process and the second etching process are anisotropic plasma etching processes.

An advantage here is that the structured masks can be transferred to the underlying layers with minimal widening.

In a possible embodiment of the production method of the present invention, the first implantation process comprises a first implantation energy in the range of 30 keV to 2700 keV.

The advantage here is that the shielding regions are produced in the trench bottom below the gate oxide to be protected, so that a maximum shielding effect is achieved without pitch loss.

According to a further aspect, an example embodiment of the present invention provides a power FinFET having control electrodes and a semiconductor body that comprises a drift layer and a second connection region, wherein the second connection region is arranged above the drift layer and wherein first trenches and second trenches extend from the second connection region into the drift layer of the semiconductor body, wherein the first trenches and the second trenches are arranged alternating relative to one another, wherein the first and second trenches typically comprise the same width, wherein shielding regions are arranged below the first trenches, wherein the shielding regions are immediately adjacent to the first trenches,
wherein a control electrode is arranged within each of the first trenches and a control electrode is arranged within each of the second trenches,
wherein the control electrode arranged in a first trench is electrically insulated from a shielding region located below the first trench, and wherein fins are arranged between the first trenches and the second trenches, wherein the fins preferably comprise a width of at most 500 nm.

An advantage here is that the short-circuit current is limited by the space-charge zone of the shielding regions and of the opposite trench wall of a second trench. Furthermore, it is advantageous that the influence of process variability on the short-circuit current and the on-resistance of the power FinFET is reduced.

In a development of the present invention, spreading regions are arranged below the second trenches.

The advantage here is that the current propagation is high and the on-resistance is low.

In a further embodiment of the present invention, the shielding regions are p-doped and have a dopant concentration of at least 1E18/cm³.

This is advantageous in that high implantation doses can be introduced cost-effectively below the trench bottom and deeper regions can be created with low implantation energies.

In one example embodiment of the present invention, the semiconductor body of the power FinFET comprises silicon carbide (SiC).

The advantage here is that aluminum, which is easily activated, can be used for implantation.

In another embodiment of the present invention, the semiconductor body of the power FinFET comprises gallium nitride (GaN).

The advantage here is that the critical field strength and the electron mobility are high.

In one embodiment of the power FinFET of the present invention, the control electrodes located in the first trenches are formed in one part.

Further advantages of the production method according to the present invention and of the power FinFET according to the present invention result from the following description of embodiments.

### BRIEF DESCRIPTION OF THE DRAWINGS

The present invention is explained below with reference to preferred embodiments and the figures.

FIG. 1 shows a method for producing a power FinFET with a one-part control electrode, according to an example embodiment of the present invention.

FIG. 2 shows a first embodiment of a power FinFET with a one-part control electrode, according to an example embodiment of the present invention.

FIG. 3A to 3K are sectional views showing production steps of the production method according to an example embodiment of the present invention.

FIG. 4 is a diagram for explaining the operation of a power FinFET according to an example embodiment of the present invention.

FIG. 5 shows a second example embodiment of a power FinFET with a one-part control electrode, according to the present invention.

### DETAILED DESCRIPTION OF EXAMPLE EMBODIMENTS

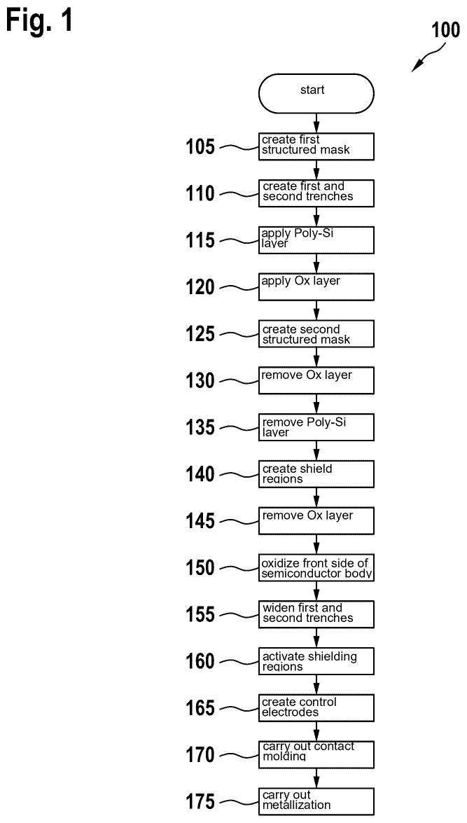

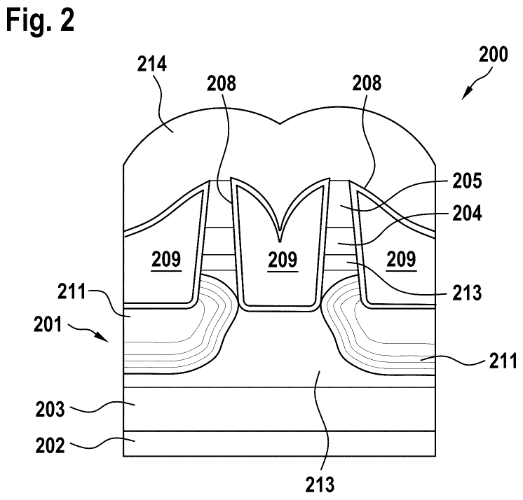

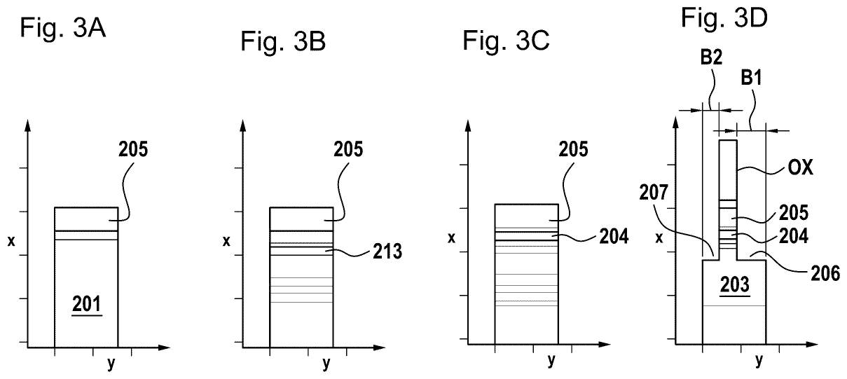

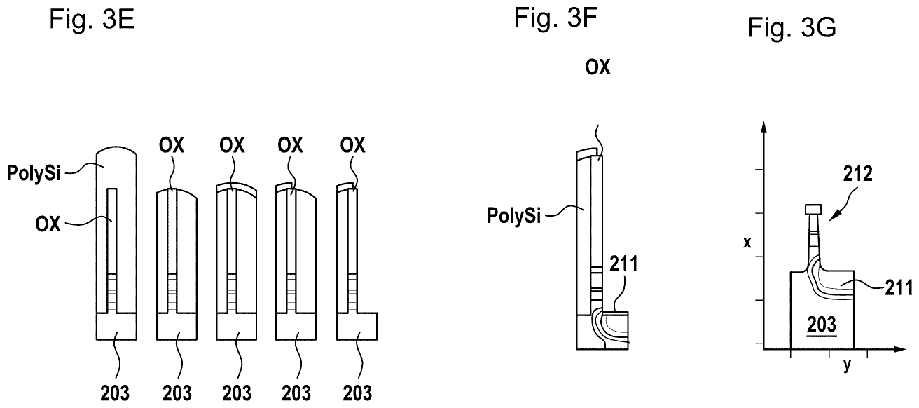

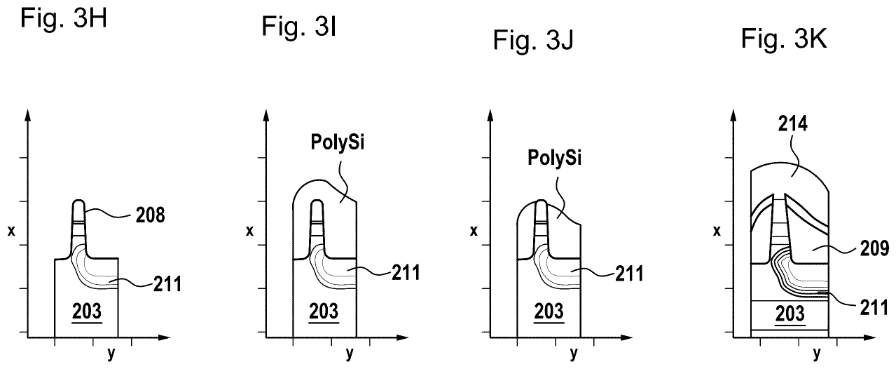

FIG. 1 shows a flow chart of a possible embodiment of a method according to the present invention for producing a power FinFET 200 with control electrodes. A power FinFET 200 with control electrodes 209 produced using the method is shown in FIG. 2. FIGS. 3A-3K show sectional views for explaining individual production steps.

The power FinFET 200 comprises a semiconductor body 201 which comprises for example silicon carbide (SiC) or gallium nitride (GaN). The power FinFET 200 comprises a first connection region 202 on the back side (bottom in FIG. 2), a drift layer 203, a channel region 204 and a second connection region 205 on the front side (top in FIG. 2).

For producing the power FinFET 200, the semiconductor wafer or semiconductor body 201 having the corresponding n-drift epitaxial layer 203 is first provided in preparatory steps 100 (see also FIG. 3A). This is followed by an n-source implantation for the second connection region 205 (FIG. 3B) and an n spreading implantation for spreading regions 213 to be produced (FIG. 3C).

In a step 105, a first structured mask M1 is created on the front side of the semiconductor body 201 with the aid of a first lithography step (FIG. 3D). The first structured mask M1 comprises oxide regions Ox, first open regions B1 and second open regions B2, wherein the first open regions B1 and the second open regions B2 of the first structured mask expose the front side of the semiconductor body 201.

In a subsequent step 110, first trenches 206 below the first open regions B1 of the mask M1 and second trenches 207 below the second open regions B2 of the mask M1 are created with the aid of a first etching process starting from the front side of the semiconductor body 201 into the drift layer 203 of the semiconductor body 201 (see FIG. 3D). In other words, the first trenches 206 and the second trenches 207 are preferably created simultaneously. The first trenches 206 and the second trenches 207 are arranged substantially parallel to one another and alternate. In a preferred embodiment, the width B2 of the second trenches 207 is typically equal to the width B1 of the first trenches 206. The first etching process performed in step 110 is preferably an anisotropic etching process. In the case of a SiC semiconductor body 201, the first etching process selects between silicon carbide (SiC), which is etched, and silicon dioxide (SiO2), silicon nitride (SiN) and silicon (Si), which are etched as little as possible.

In a subsequent step 115, a polysilicon layer Poly-Si is applied onto the front side of the semiconductor body 201 so that the first trenches 206 and second trenches 207 are filled (see also FIG. 3E at left).

In a subsequent step 120, an isotropic oxide layer Ox is applied to the front side of the semiconductor body 201.

In a subsequent step 125, a second structured mask M2 is created on the isotropic oxide layer with the aid of a second lithography step, wherein the second structured mask M2 is open above the first trenches 206 (see FIG. 3E).

In a subsequent step 130, the isotropic oxide layer Ox above the first trenches 206 is removed with the aid of a second etching process (see FIG. 3E). The second etching process performed in step 130 is preferably an anisotropic etching process. The second etching process etches the oxide layer, in particular silicon dioxide (SiO2), whereas silicon (Si) is etched as little as possible

In a subsequent step 135, the polysilicon layer Poly-Si within the first trenches 206 is removed with the aid of a third etching process (see FIG. 3E at the right). The third etching process performed in step 135 removes silicon (Si). However, the third etching process is very selective to silicon dioxide (SiO2), silicon nitride (SiN) and silicon carbide (SiC), which are not etched.

In a subsequent step 140, shielding regions 211 are created below the first trenches 206 with the aid of a first implantation process (FIG. 3F). The first implantation energy is between 30 keV and 2700 keV. The created shielding regions 211 are p-doped.

In a subsequent step 145, the isotropic oxide layer Ox above the second trenches 207 and the polysilicon layer Poly-Si within the second trenches 207 are removed with the aid of a fourth etching process (FIG. 3G). The fourth etching process performed in step 145 etches the oxide layer, particularly silicon dioxide (SiO2), and silicon (Si), but is selective to silicon nitride (SiN) and silicon carbide (SiC), which are not etched.

In a subsequent step 150, the front side of the semiconductor body 201 is oxidized so that a further oxide layer is arranged on the front side of the semiconductor body 201. The oxide layer comprises a thickness of at least 10 nm.

In a subsequent step 155, the first trenches 206 and the second trenches 207 are widened with the aid of a fifth etching process so that fins 212 are formed between the first trenches 206 and the second trenches 207. The fins 212 formed preferably comprise a width of less than 500 nm (FIG. 3G). The oxide from step 150 is selectively etched wet-chemically. The fifth etching process in the case of a SiC semiconductor body selects between oxide, in particular silicon dioxide (SiO2), which is etched, and silicon carbide (SiC) and silicon nitride (SiN), which are not etched.

The steps 150 and 155 are carried out cyclically depending on the fin width of the fins 212 to be achieved. In other words, the front side of the semiconductor body 201 is oxidized multiple times, wherein an etching step is carried out between the oxidation steps. The widening of the trenches 206, 207 (see FIG. 3G) is thus carried out without adjustment, or in a self-adjusting manner. The lateral oxidation rate exceeds the vertical oxidation rate by approximately a factor of two.

In a step 160, the shielding regions 211, which lie below the first trenches 206, can then be activated by means of annealing. The annealing is typically carried out at about 1700° C. Furthermore, a deposition of a gate oxide 208 can be carried out (FIG. 3H).

In a subsequent step 165, the control electrodes 209 are created within the first trenches 206 and within the second trenches 207. For this purpose, the electrode material for the control electrodes 209, in particular polysilicon, is first deposited in a layer thickness so that all trenches 206, 207 (i.e., both the first trenches 206 and the second trenches 207) are completely filled (see FIG. 3I). In a subsequent sixth etching process in step 165, this has the result that not only does a spacer remain on the trench side walls of the trenches 206, 207; rather, all trenches 206, 207 remain completely filled with the electrode material for the control electrode 209, in particular with polysilicon Poly-Si (see FIG. 3J). The contact to the p-shielding regions 211, which are arranged below every second trench (i.e., below the first trenches 206), is therefore not made by a contact in the trench, but by a contact at the end of the cell field, or by a deep p-connection region implanted at periodic intervals along the fin 212. Furthermore, in step 165 a gate polysilicon insulation is carried out. This comprises an oxide deposition and/or poly-reoxidation.

In a further step 170, contact molding is carried out at the bottom of the trench, at the fin tip of the fin 212 and at the rear side.

Finally, in a further step 175, a metallization 214 of the front and back sides is carried out (see also FIG. 3K).

FIG. 2 shows a possible embodiment of a power FinMOSFET 200 produced using the method according to the present invention. After the fins 212 have been molded, the first trenches 206 are widened to such an extent that there is sufficient space for the gate or control electrode 209, the gate and insulation oxides 208 and the p-doped shielding regions 211. The second trenches 207 created between the first trenches 206 are made with the same width as the first trenches 206, so that in the poly-recess process in the step 170 the trench floor or trench bottom is not exposed either in the first trenches 206 or in the second trenches 207. The n-region below the second trench 207 thus remains isolated from the gate or control electrode 209 and the source contact. The under-scattering of the p-shield implantation into the first trenches 206 together with the width of the second trenches 207 and the resulting width of the fins 212 controls the distance of the p-shielding region 211 from the opposite trench edge. With these design parameters, an optimum of on-resistance Ron, short-circuit current Isc and field strength in the oxide at the trench bottom of the second trench 207 can be set. The p-channel region can be contacted in the third dimension via p+ doped regions that alternate with the n-source regions along the fin 212.

The power FinFET 200 shown in FIG. 2 has a semiconductor body 201 that comprises a first connection region 202, a drift layer 203, a channel region 204 and a second connection region 205.

The first connection region 202 of the semiconductor body 201 preferably functions as a drain connection and the second connection region 205 of the semiconductor body 201 preferably functions as a source connection. The drift layer 203 of the semiconductor body 201 is arranged on the first (rear) connection region 202 (bottom in FIG. 2). The channel region 204 of the semiconductor body 201 is arranged on the drift layer 203. The second connection region 205 of the semiconductor body 201 or the source connection 205 is arranged on the channel region 204 of the semiconductor body 201. The second connection region or source connection 205 is located on the front side of the semiconductor body 201 (top in FIG. 2). The semiconductor body 201 preferably comprises silicon carbide (SiC) or gallium nitride (GaN).

Starting from the front side of the semiconductor body 201, first trenches 206 and second trenches 207 preferably extend into the drift layer 203 of the semiconductor body 201, wherein the second trenches 207 typically comprise the same width as the first trenches 206. The first trenches 206 and the second trenches 207 are arranged in an alternating manner. Shielding regions 211, which are preferably p-doped, are arranged below the first trenches 206. The shielding regions 211 directly adjoin a trench bottom of the first trenches 206. The dopant concentration of the shielding regions 211 is at least 1E18/cm³.

A control electrode 209, which acts as a gate connection, is arranged within each first trench 206. The control electrode 209 is electrically insulated from the shielding region 211 with the aid of an oxide layer 208. Between the first trenches 206 and the second trenches 207, fins 212 are arranged which preferably comprise a width of less than 500 nm.

With the aid of the production method according to the present invention, it is achieved that the shielding regions 211 below the first trenches 206 are further apart from one another than the shielding regions 211 are from the opposite trench walls or side walls of the second trenches 207. As a result, the short-circuit current Isc is not limited by the collision of the space-charge zones of two shielding regions, but by the space-charge zone of each p-doped shielding region 211, which displaces or pushes the current against the opposite trench wall of a second trench 207. The low sensitivity to process variability is achieved by the fact that, in the event of a short circuit, the trench wall of the second trench 207 forms an accumulation channel due to the positive gate voltage, which accumulation channel cannot be cleared by the space-charge zone of the p-doped shielding region 211.

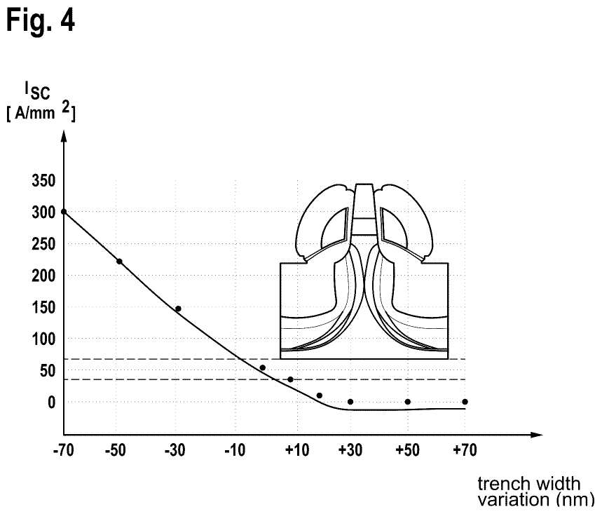

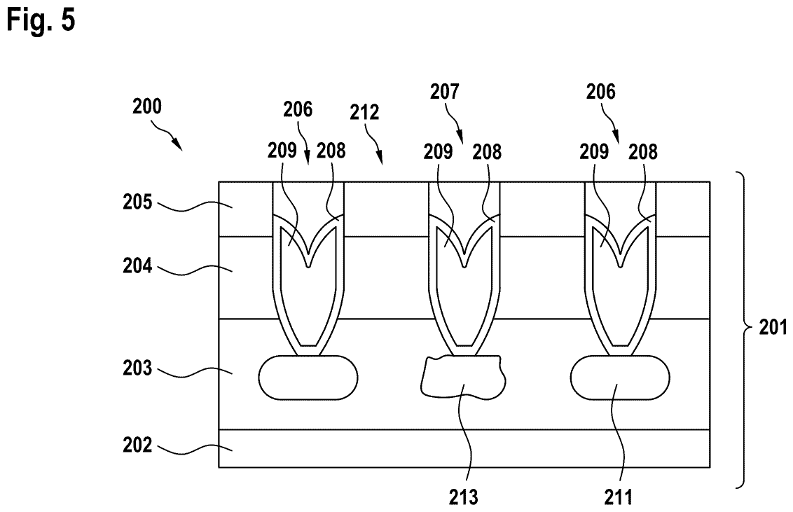

FIG. 4 shows the consequences for a short-circuit current Isc when the p-shielding regions have different distances relative to one another using the example of an implantation through a trench in which the trench width is varied. As soon as the p-shielding regions are only 10 nm too far apart (10 nm narrower trench), the short-circuit current Isc is no longer sufficiently limited and is above the tolerance limit. Likewise, a trench that is 30 nm wider (or an implantation mask opening that is 30 nm wider) results in the neighboring p-regions touching one another, the JFET is completely closed and thus no current flows at all and the on-resistance of the power FinFET consequently approaches infinity.

In the power FinFET 200 according to the present invention with alternating p-shielding regions 211, this is prevented by implanting only in every second trench, i.e. in the first trenches 206. As a result, the effect limiting the short-circuit current Isc between a p-shielding region 211 and a trench edge is created, which is less sensitive to process variations.

In one possible embodiment, the p-shielding regions 211 are implanted by implantation with a lithographically structured mask.

Alternatively, the implantation can also be carried out through a trench. In both cases, the distance between two adjacent p-shielding regions 211 is subject to a certain process fluctuation.

A further advantage is that below a second trench 207 (below which there is no p-shielding region) the distance between two adjacent p-shielding regions 211 is increased, thus creating a space in which the electric current I can propagate. This spreading region 213 results in the on-resistance of the power FinFET 200 being reduced.

In addition, it is possible to n-dope the spreading region 213 slightly higher than the n-drift zone 203 in order to further increase the current propagation effect. This can be realized by means of implanting into the non-p-implanted trenches. As a result, the implantation energies required to produce the spreading region 213 are not as high as those required for an initial implantation through the unstructured wafer.

In an exemplary embodiment, the first structured mask M1 comprises nitride regions (in particular SiN), which are located between the front side and the oxide regions. The nitride regions protect the front side or surface of the fins 212, since oxidation of the fin top is prevented in this way in step 150. The nitride regions are removed in an intermediate step (not shown in the flow diagram in FIG. 1) between step 155 and step 160.

In a possible further embodiment, in the preparatory steps 100, the spreading regions 213 can be implanted below the second trenches 207 with the aid of an implantation process. The spreading regions 213 are n-doped and comprise a higher doping than the n-doped drift layer 203. As a result, the current propagation effect below the second trenches 207 is enhanced. The implantation process preferably comprises an implantation energy that comprises a value in a range between 60 keV and 2500 keV.

The power FinFET 200 is used primarily in DC/DC converters and inverters of an electric drive train of electric or hybrid vehicles, as well as in vehicle chargers.

1-13. (canceled)

14. A method for producing a power FinFET having control electrodes, wherein the power FinFET includes a semiconductor body which includes a second connection region and a drift layer, wherein the second connection region forms a front side of the semiconductor body, the method comprising the following steps:
creating a first structured mask on the front side of the semiconductor body using a first lithography step, wherein the first structured mask includes oxide regions, first open regions, and second open regions, wherein the first open regions and the second open regions expose the front side of the semiconductor body;
creating first trenches below the first open regions of the first structured mask and second trenches below the second open regions of the first structured mask using a first etching process starting from the front side of the semiconductor body into drift layer, wherein the first trenches and the second trenches are arranged substantially parallel to one another and alternate, wherein the second trenches are substantially the same width as the first trenches;
applying a polysilicon layer onto the front side of the semiconductor body so that the first trenches and second trenches are filled;
applying an isotropic oxide layer to the front side of the semiconductor body;
creating a second structured mask on the isotropic oxide layer using a second lithography step, wherein the second structured mask is open above the first trenches;
removing the isotropic oxide layer above the first trenches using a second etching process;
removing the polysilicon layer within the first trenches using a third etching process;
creating shielding regions below the first trenches using a first implantation process;
removing the isotropic oxide layer above the second trenches and the polysilicon layer within the second trenches using a fourth etching process;
oxidizing the front side so that a further oxide layer is arranged on the front side;
widening the first trenches and the second trenches using a fifth etching process so that fins are formed between the first trenches and the second trenches, wherein the fins have a width of less than 500 nm;
activating the shielding regions by annealing; and
creating control electrodes within the first trenches and within the second trenches.

15. The method according to claim 14, wherein, for creating the control electrodes, an electrode material for the control electrodes, including polysilicon, is deposited in a layer thickness in such a way that the first and second trenches are completely filled, wherein after a subsequent etching process the first and second trenches remain completely filled with the electrode material for the control electrode.

16. The method according to claim 14, wherein the first structured mask includes nitride regions, wherein the oxide regions are arranged on the nitride regions.

17. The method according to claim 14, wherein spreading regions are created below the second trenches using a second implantation process that includes a second implantation energy in a range between 60 keV and 2500 keV.

18. The method according to claim 14, wherein the first etching and the second etching process are anisotropic plasma etching processes.

19. The method according to claim 14, wherein the first implantation process includes a first implantation energy in a range of 30 keV to 2700 keV.

20. The method according to claim 14, wherein the control electrodes formed in the first trenches are formed in one piece.

21. A power FinFET, comprising:
a semiconductor body that includes includes a drift layer and a second connection region;
wherein the second connection region is arranged above the drift layer, and first trenches and second trenches extend from the second connection region into the drift layer of the semiconductor body;
wherein the first trenches and the second trenches are arranged alternating relative to one another and the second trenches have substantially the same width as the first trenches;
wherein control electrodes are arranged within the first trenches, and control electrodes are arranged within the second trenches;
wherein each control electrode arranged in a first trench is electrically insulated from a shielding region located below the first trench; and
wherein between the first trenches and the second trenches, fins are arranged which have a width of at most 500 nm.

22. The power FinFET according to claim 21, wherein spreading regions are arranged below the second trenches.

23. The power FinFET according to claim 21, wherein the shielding regions arranged below the first trenches are p-doped and include a dopant concentration of at least 1E18/cm³.

24. The power FinFET according to claim 21, wherein the semiconductor body includes silicon carbide (SiC).

25. The power FinFET according to claim 21, wherein the semiconductor body includes gallium nitride (GaN).

26. The power FinFET according to claim 21, wherein the control electrodes formed in the first trenches are formed in one piece.
